(19) United States
(12) Patent Application Publication
(10) Pub. No.: US 2016/0042926 A1
(43) Pub. Date: Feb. 11, 2016

(54) PLASMA PROCESSING APPARATUS AND FOCUS RING

(71) Applicant: TOKYO ELECTRON LIMITED, Tokyo (JP)

(72) Inventors: Takuya ISHIKAWA, Miyagi (JP); Naoyuki SATOH, Miyagi (JP); Keita KAMBARA, Miyagi (JP); Ryo SASAKI, Miyagi (JP)

(73) Assignee: TOKYO ELECTRON LIMITED, Tokyo (JP)

(21) Appl. No.: 14/817,877

(22) Filed: Aug. 4, 2015

(30) Foreign Application Priority Data
Aug. 11, 2014 (JP) 2014-163619

(51) Int. Cl. H01J 37/32; C23C 16/46; C23C 16/458; C23C 16/50

(52) U.S. Cl. CPC H01J 37/32724; H01J 37/32009; C23C 16/50; C23C 16/46; C23C 16/458

(57) ABSTRACT

Disclosed is a plasma processing apparatus including a focus ring installed outside a substrate mounted on a mounting table including a temperature control mechanism. The focus ring is configured to be in contact with the mounting table via a heat transfer sheet. A heat insulating layer having a heat conductivity lower than that of the focus ring is provided on a surface of the focus ring at a side of the heat transfer sheet among surfaces of the focus ring.

### CROSS-REFERENCE TO RELATED APPLICATIONS

This application is based on and claims priority from Japanese Patent Application No. 2014-163619, filed on Aug. 11, 2014, with the Japan Patent Office, the disclosure of which is incorporated herein in its entirety by reference.

### TECHNICAL FIELD

The present disclosure relates to a plasma processing apparatus and a focus ring.

### BACKGROUND

In a plasma processing apparatus that performs a plasma processing on a semiconductor wafer (hereinafter, referred to as a “wafer” as well), a mounting table configured to mount a wafer thereon is installed within a vacuum chamber. At the outer peripheral side of the mounting table, a focus ring is placed to surround the outer periphery of the wafer. The focus ring extends a plasma distribution region occurring above the wafer to an area above the focus ring in addition to the area above the wafer so as to secure uniformity of a processing such as, for example, etching, performed on the entire surface of the wafer.

The focus ring is directly exposed to plasma together with the wafer so that the focus ring is heated by the heat input from the plasma. Accordingly, a heat transfer sheet is interposed between the focus ring and the mounting table so as to enhance the adhesion therebetween so that the heat transfer rate of the focus ring and the mounting table is enhanced and the heat of the focus ring is diffused to the mounting table side (see, e.g., Japanese Patent Laid-Open Publication No. 2008-171899.

### SUMMARY

According to an aspect of the present disclosure, in order to solve the problem described above, there is provided a plasma processing apparatus includes a focus ring installed outside a substrate mounted on a mounting table including a temperature control mechanism. The focus ring is configured to be in contact with the mounting table via a heat transfer sheet. A heat insulating layer having a heat conductivity lower than that of the focus ring is provided on a surface of the focus ring at a side of the heat transfer sheet among the surfaces of the focus ring.

The foregoing summary is illustrative only and is not intended to be in any way limiting. In addition to the illustrative aspects, embodiments, and features described above, further aspects, embodiments, and features will become apparent by reference to the drawings and the following detailed description.

### BRIEF DESCRIPTION OF THE DRAWINGS

FIG. 1 is a view illustrating an exemplary vertical section of a plasma processing apparatus according to an exemplary embodiment.

FIG. 2 is a view illustrating a focus ring according to an exemplary embodiment and an example of a heat insulating structure around the focus ring.

FIG. 3 is a view illustrating an example of a temperature change around the focus ring according to an exemplary embodiment.

FIG. 4 is a view illustrating an example of a method of processing a heat insulating layer according to an exemplary embodiment.

### DETAILED DESCRIPTION

In the following detailed description, reference is made to the accompanying drawings, which form a part hereof. The illustrative embodiments described in the detailed description, drawing, and claims are not meant to be limiting. Other embodiments may be utilized, and other changes may be made without departing from the spirit or scope of the subject matter presented here.

In a high temperature plasma process that applies a high frequency power with high energy into a chamber, the top surface of the focus ring which is exposed to the plasma is heated, and thus, the surface of the heat transfer sheet which is in contact with the focus ring is heated. Then, the temperature within the chamber may become higher by the high temperature process. For example, when the temperature within the chamber rises by 50° C. or more, the temperature of the surface of the heat transfer sheet with which the focus ring is in contact also rises.

As the temperature of the contact surface with the focus ring becomes higher, the heat transfer sheet is degraded so that the life span of the heat transfer sheet is reduced.

In connection with the problems described above, in one aspect, the present disclosure is to suppress of the deterioration of a heat transfer sheet.

In order to solve the problem described above, according to an aspect of the present disclosure, there is provided a plasma processing apparatus includes a focus ring installed outside a substrate mounted on a mounting table including a temperature control mechanism. The focus ring is configured to be in contact with the mounting table via a heat transfer sheet. A heat insulating layer having a heat conductivity lower than that of the focus ring is provided on a surface of the focus ring at a side of the heat transfer sheet among the surfaces of the focus ring.

In the plasma processing apparatus described above, the focus ring is formed integrally with the heat insulating layer.

In the plasma processing apparatus described above, the heat insulating layer includes a porous material having a predetermined porosity.

In the plasma processing apparatus described above, the heat insulating layer includes at least one of zirconia, quartz, silicon carbide, and silicon nitride.

According to another aspect, there is provided a focus ring installed outside a substrate mounted on a mounting table including a temperature control mechanism within a chamber where a plasma processing is performed. The focus ring is configured to be in contact with the mounting table via a heat transfer sheet. A heat insulating layer having a heat conductivity lower than that of the focus ring is provided on a surface of the focus ring at a side of the heat transfer sheet among surfaces of the focus ring.

According to the aspects, deterioration of the heat transfer sheet can be suppressed.

Hereinafter, exemplary embodiments of the present disclosure will be described with reference to the accompanying drawings. In addition, in the specification and drawings, the substantially same components will be denoted by the same reference symbols, and redundant descriptions will be omitted.

### Configuration of Plasma Processing Apparatus

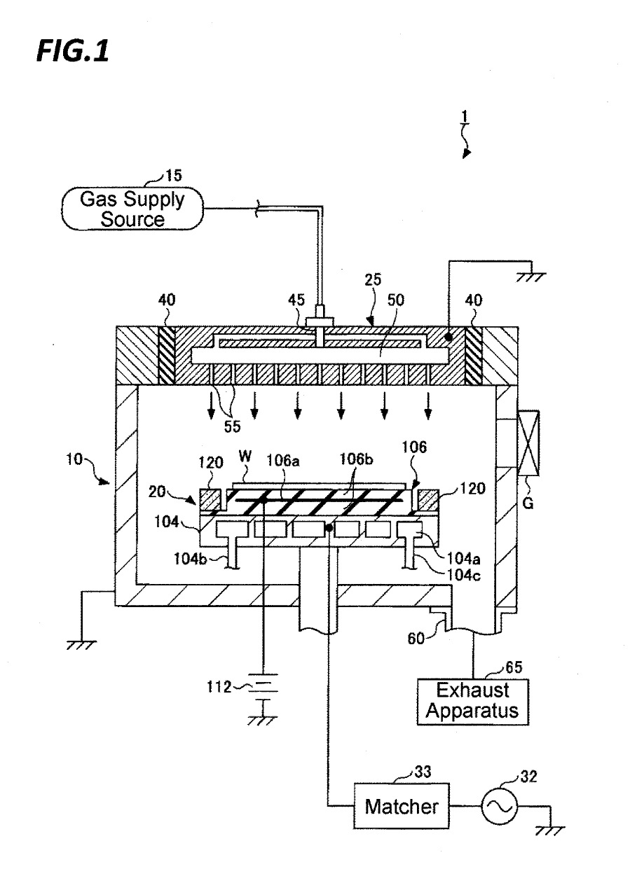

First, a plasma processing apparatus according to an exemplary embodiment of the present disclosure will be described by way of an example. The plasma processing apparatus refers to an apparatus that performs a plasma processing such as, for example, a plasma etching, a plasma chemical vapor deposition (CVD) on a wafer W placed within a chamber. FIG. 1 illustrates an example of a vertical section of a plasma processing apparatus 1 according to an exemplary embodiment. In the present exemplary embodiment, descriptions will be made on a parallel flat plate plasma processing apparatus 1 in which a lower electrode and an upper electrode are arranged opposite to each other within a chamber 10, and a processing gas is supplied from the upper electrode into the chamber, by way of an example.

The chamber 10 is formed of a conductive material such as, for example, aluminum. The chamber 10 is grounded. Within the chamber 10, a mounting table 20 is installed to mount a wafer W thereon. The mounting table 20 also serves as a lower electrode.

The mounting table 20 is provided with an electrostatic chuck 106. The electrostatic chuck 106 has a configuration with a chuck electrode 106a being sandwiched between insulators 106b. The chuck electrode 106a is connected with a direct current (DC) power source 112. When a DC voltage is applied to the chuck electrode 106a from the DC power source 112, the wafer W is attracted to the electrostatic chuck 106 by a Coulomb force.

The mounting table 20 is supported by a support 104. Within the support 104, a coolant flow path 104a is formed. The coolant flow path 104a is connected with a coolant inlet pipe 104b and a coolant outlet pipe 104c. Within the coolant flow path 104a, for example, cooling water is circulated as the coolant.

To the rear surface of the wafer W, a heat transfer gas such as, for example, helium (He) is supplied from a heat transfer gas supply source (not illustrated). With this configuration, the electrostatic chuck 106 is subjected to a temperature control by the cooling water circulated in the coolant flow path 104a and the heat transfer gas supplied to the rear surface of the wafer W. As a result, it is possible to control the wafer to have a predetermined temperature.

In addition, the mounting table 20 may be provided with a heater (not illustrated) so as to control the wafer to have a predetermined temperature by the heater, the coolant, and the heat transfer gas. The heater, the coolant, and the heat transfer gas form an example of a temperature control mechanism for controlling the temperature of the mounting table 20.

On the mounting table 20, a focus ring 120 is arranged to surround the outer periphery of the wafer W. In the present exemplary embodiment, the focus ring 120 is formed of silicon (Si). However, the focus ring 120 may be formed of quartz or silicon carbide (SiC), for example.

The mounting table 20 is connected with a high frequency power source 32 via a matcher 33. The high frequency power source 32 supplies, for example, a high frequency power of 40 MHz. The matcher 33 serves to make the internal impedance of the high frequency power source 32 and the load impedance apparently match with each other when plasma is generated within the chamber 10.

On the ceiling surface of the chamber 10, a gas shower head 25 is formed through a shield ring 40 that covers the peripheral edge thereof. The gas shower head 25 also serves as an upper electrode. The gas shower head 25 is connected with a gas supply source 15. The gas supply source 15 supplies a gas according to a plasma process to be executed. The gas is introduced from a gas introduction port 45, diffused in a diffusion chamber 50, and introduced into the chamber 10 from a plurality of gas supply holes 55.

An exhaust port 60 is formed in the bottom surface of the chamber 10, and the inside of the chamber 10 is exhausted by an exhaust apparatus connected to the exhaust port 60 so that the inside of the chamber 10 is managed in a predetermined decompressed state. A gate valve G is installed on the side wall of the chamber 10. The gate valve G is opened when the wafer W is carried into the chamber 10, and closed when the wafer W is carried out to the outside of the chamber 10.

The whole configuration of the plasma processing apparatus 1 according to the present exemplary embodiment has been described above. By the plasma processing apparatus 1 with this configuration, a desired plasma processing is performed on a wafer W. For example, in the case where a plasma etching process is performed, the opening/closing of the gate valve G is controlled so that the wafer W is carried into the chamber 10 and mounted on the mounting table 20. Subsequently, an etching gas is supplied into the chamber 10 from the gas shower head 25, and a high frequency power is applied to the mounting table 20. Then, the plasma etching is performed on the wafer W by the generated plasma. After the plasma etching, the opening/closing of the gate valve G is controlled so that the wafer W is carried out from the chamber 10.

### Focus Ring and Peripheral Structure thereof

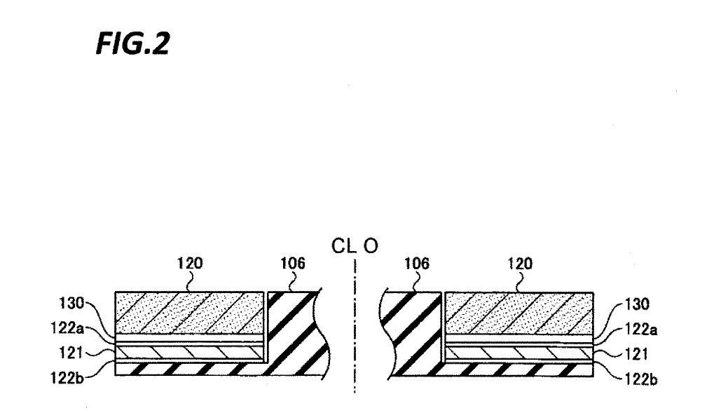

Next, descriptions will be made on the focus ring 120 according to the present exemplary embodiment and the peripheral structure thereof with reference to FIG. 2. FIG. 2 illustrates the focus ring 120 according to the present exemplary embodiment and an exemplary insulating structure therearound.

The focus ring 120 extends the plasma distribution region generated above the wafer W to the area above the focus ring 120 in addition to the area above the wafer W so as to secure uniformity of the plasma processing such as, for example, etching, performed on the entire surface of the wafer W.

The focus ring 120 is directly exposed to the plasma together with the wafer W, and thus, the focus ring 120 is heated by the heat input from the plasma. Thus, polymer sheets 122a, 122b are provided between the focus ring 120 and the mounting table 20. In the present exemplary embodiment, a ring member 121 formed of aluminum is interposed between the mounting table 20 and the focus ring 120. Accordingly, between the focus ring 120 and the ring member 121, and between the ring member 121 and the mounting table 20, the polymer sheets 122a, 122b (which may also be referred to as a “polymer sheet 122”) are provided.

The ring member 121 does not necessarily have to be provided. However, even if the ring member 121 is not provided, the polymer sheet 122 is installed between the focus ring 120 and the mounting table 20.

The polymer sheet 122 enhances adhesion between the focus ring 120 and the mounting table 20 so as to improve the heat transfer rate between the focus ring 120 and the mounting table 20. In this way, the heat input to the focus ring 120 may be spread to the mounting table 20 side through the ring member 121.

The polymer sheet 122 is an exemplary heat transfer sheet that has a predetermined level or more in heat conductivity, radical resistance, and hardness. The polymer sheet is formed using a silicon material as a main material. The polymer sheet is excellent in heat resistance and plasma resistance compared with other resin materials and compatible with a filler [alumina (Al₂O₃)] that is added so as to adjust heat conductivity. Thereby, the heat conductivity of the polymer sheet 122 is adjusted to 1 W/m·K to 20 W/m·K, and the hardness is adjusted to about 20 to 80 in Ascar C.

The present exemplary embodiment includes a heat insulating layer 130, having a heat conductivity lower than that of the focus ring 120, on the bottom surface of the focus ring 120 (the surface that is in close contact with the polymer sheet 122). The focus ring 120 is formed integrally with the heat insulating layer 130 such that 20% to 30% of the focus ring 120 from the bottom surface thereof becomes the heat insulating layer 130. An example of integrally forming the focus ring 120 and the heat insulating layer 130 is to integrally baking the focus ring 120 and the heat insulating layer 130. Other examples of integrally forming the focus ring 120 and the heat insulating layer 130 may include a method of bonding the heat insulating layer 130 to the bottom surface of the focus ring 120 using an adhesive, and a method of forming the heat insulating layer 130 on the bottom surface of the focus ring 120 through spraying or coating.

The heat insulating layer 130 includes at least one of zirconia (ZrO₂), quartz, silicon carbide (SiC), and silicon nitride (SiN). The heat insulating layer 130 may be a porous material formed of, e.g., silicon (Si) and having a predetermined porosity.

### Temperature Change around Focus Ring

The focus ring 120 is formed of single-crystal silicon that is a highly heat-conductive material, and the ring member 121 is formed of aluminum as described above. In this case, a change in temperature hardly occurs within the focus ring 120 and within the ring member 121. That is, as the temperature change around the focus ring 120, the temperature difference between the inside of the polymer sheet 122 and interfaces between the polymer sheet 122 and members in contact with the polymer sheet 122 is predominant. The interfaces between the polymer sheet 122 and the members in contact with the polymer sheet 122 include the interface between the focus ring 120 (the heat insulating layer 130) and the polymer sheet 122, the interface between the polymer sheet 122 and the ring member 121, and the interface between the ring member 121 and the electrostatic chuck 106. Accordingly, the heat gradient increases in these interfaces.

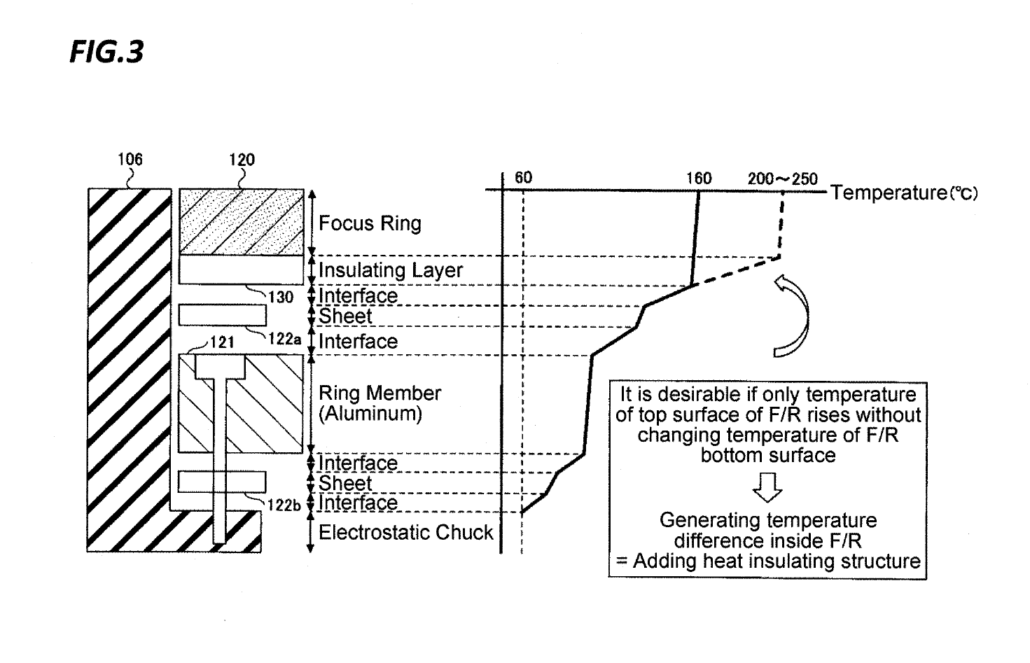

FIG. 3 is illustrates an example of a temperature change around the focus ring 120 according to the present exemplary embodiment. It can be seen that the temperature changes (heat gradients) within the focus ring 120, within the ring member 121, and within the polymer sheet 122 are small compared with the temperature changes occurring in the interfaces thereof. In particular, the focus ring 120 according to the present exemplary embodiment is used within the chamber 10 that is in a vacuum condition. For this reason, the influence of the temperature change on the thermal resistance, which is caused in the interfaces, is great compared with a case where the chamber is in an atmospheric condition.

In addition, according to the present exemplary embodiment, the heat insulating layer 130, having a heat conductivity lower than the heat conductivity of the focus ring 120, is formed on the bottom surface of the focus ring 120. Thereby, the temperature change occurring within the focus ring 120 including the heat insulating layer 130 may be made to be larger than the temperature change occurring within the focus ring 120 that does not include the heat insulating layer 130.

When the polymer sheet 122 is deteriorated, the heat transfer performance is lost. For this reason, it is desirable not to deteriorate the polymer sheet 122.

The polymer sheet 122 is most deteriorated in the surface that is in contact with the focus ring 120, and is dependent on the temperature of the surface that is in contact with the focus ring 120 (i.e., the top surface of the polymer sheet 122). Since the bottom surface of the polymer sheet 122 is in contact with the ring member 121 made of aluminum, the temperature of the bottom surface is lower than the temperature of the top surface of the polymer sheet 122. Accordingly, the temperature of the top surface of the polymer sheet 122 is important.

Meanwhile, according to the present exemplary embodiment, the heat insulating layer 130 is integrally formed on the focus ring 120. Therefore, as indicated by a dotted line in FIG. 3, even when the temperature of the top surface of the focus ring 120 increases to 200° C. to 250° C. by the heat input from plasma in a high temperature process, the temperature of the bottom surface of the focus ring 120, i.e. the temperature of the top surface of the polymer sheet 122 may remain at about 160° C. by the temperature change generated within the focus ring 120. As a result, even when the temperature of the top surface of the focus ring 120 rises by, for example, 50° C. or more, the temperature of the top surface of the polymer sheet 122 does not rise, and as a result, the deterioration of the polymer sheet 122 may be suppressed and the reduction of the shelf life of the polymer sheet 122 may be avoided.

### Heat Insulating Layer

Referring to FIG, 4, descriptions will be made on a material or a processing method of the insulating layer 130 formed on the focus ring 120 (“Processing Method” 200), a specification of the heat insulating layer 130 (“Specification” 210), and a temperature difference inside the focus ring 120 when the heat insulating layer 130 is formed (“Temperature Difference in F/R (° C.)” 220).

### Plasma Spraying

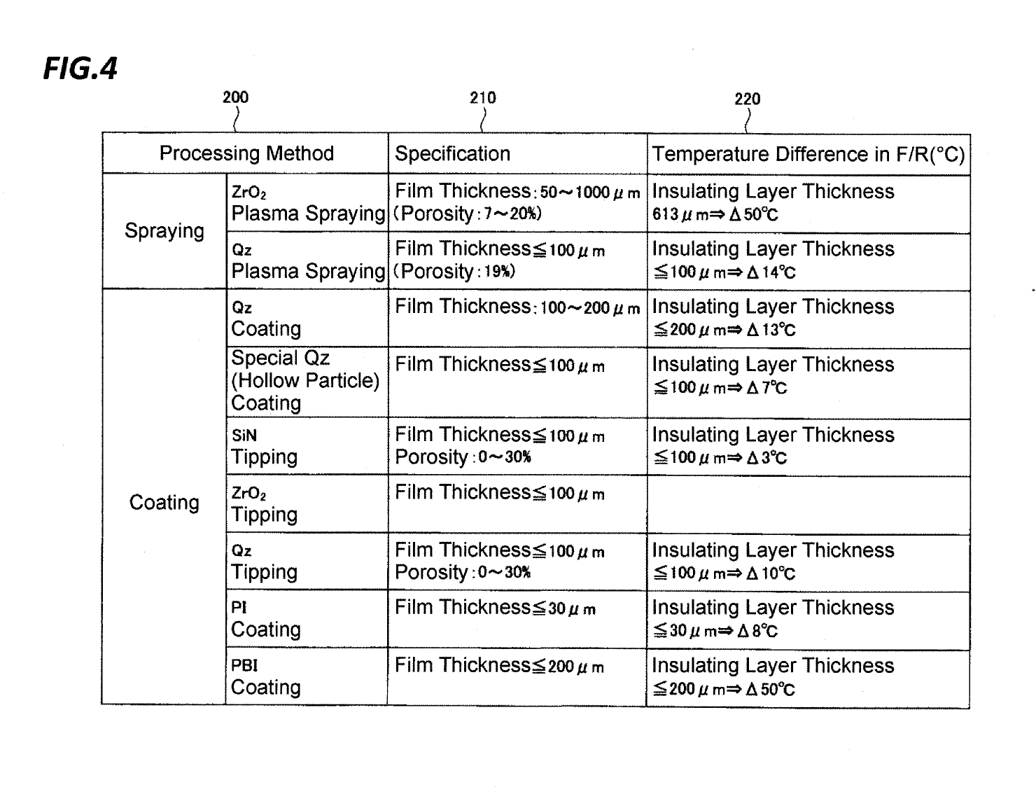

As indicated in “Processing Method” 200 in FIG. 4, the heat insulating layer 130 may be formed integrally with the focus ring 120 through plasma spraying under the atmospheric pressure. FIG. 4 illustrates an example in which a heat insulating layer 130 is formed on the focus ring 120 through plasma spraying of zirconia (ZnO₂) and quartz (Qz).

In one example of the heat insulating layer 130 of zirconia formed through the plasma spraying, the film thickness of the heat insulating layer 130 was 50 μm to 1000 μm and the porosity of the heat insulating layer 130 was 7% to 20%, as indicated in “Specification” 210 in FIG. 4. In addition, in such a case, the temperature difference within the focus ring was 50° C. when the film thickness of the heat insulating layer 130 was 613 μm, as indicated in “Temperature Difference In F/R (° C.)” 220.

In one example of the heat insulating layer 130 of quartz formed through plasma spraying, the film thickness of the heat insulating layer 130 was 100 μm or less and the porosity was 19% as indicated in “Specification” 210. In addition, in this case, the temperature difference within the focus ring was 14° C. when the film thickness of the heat insulating layer 130 was 100 μm or less, as indicated in “Temperature Difference in F/R (° C.)” 220 in FIG. 4.

### Coating

The heat insulating layer 130 may be formed integrally with the focus ring 120 through coating or dipping as indicated in “Processing Method” 200. In the coating or dipping, fluid including at least one material among zirconia, quartz, silicon carbide, and silicon nitride is coated on the bottom surface of the focus ring 120 and formed integrally with the focus ring 120 through baking.

In one example of the heat insulating layer 130 of quartz formed through coating, the film thickness of the heat insulating layer 130 was 100 μm to 200 μm, as indicated in “Specification” 210. In addition, in such a case, the temperature difference within the focus ring was 13° C. when the film thickness of the heat insulating layer 130 was 200 μm or less, as indicated in “Temperature Difference in F/R (° C.)” 220.

In one example of the heat insulating layer 130 of special quartz of hollow particles formed through coating, the film thickness of the heat insulating layer 130 was 100 μm or less, as indicated in “Specification” 210. In addition, in such a case, the temperature difference within the focus ring was 7° C. when the film thickness of the heat insulating layer 130 was 100 μm or less, as indicated in “Temperature Difference in F/R (° C.)” 220.

In one example of the heat insulating layer 130 of silicon nitride formed through dipping, the film thickness of the heat insulating layer 130 was 100 μm or less and the porosity was 0% to 30%. In addition, in such a case, the temperature difference within the focus ring was 3° C. when the film thickness of the heat insulating layer 130 was 100 μm or less, as indicated in “Temperature Difference in F/R (° C.)” 220.

In one example of the heat insulating layer 130 of zirconia formed through dipping, the film thickness of the heat insulating layer 130 was 100 μm or less.

In one example of the heat insulating layer 130 of quartz formed through dipping, the film thickness of the heat insulating layer 130 was 100 μm or less and the porosity was 0% to 30%. In addition, in such a case, the temperature difference within the focus ring was 10° C. when the film thickness of the heat insulating layer 130 was 100 μm or less, as indicated in “Temperature Difference in F/R (° C.)” 220.

In one example of the heat insulating layer 130 of polyimide (PI) formed through coating, the film thickness of the heat insulating layer 130 was 30 μm or less. In addition, in such a case, the temperature difference within the focus ring was 8° C. when the film thickness of the heat insulating layer 130 was 30 μm or less, as indicated in “Temperature Difference in F/R (° C.)” 220.

In one example of the heat insulating layer 130 of polybenzimidazole (PBI) formed through coating, the film thickness of the heat insulating layer 130 was 200 μm or less. In addition, in such a case, the temperature difference within the focus ring was 50° C. when the film thickness of the heat insulating layer 130 was 200 μm or less, as indicated in “Temperature Difference in F/R (° C.)” 220.

### Bonding

The heat insulating layer 130 may be formed integrally with the focus ring 120 by bonding the heat insulating layer 130 to the focus ring 120 using an adhesive. In such a case, the heat insulating layer 130 may be formed of quartz, special porous quartz, and silicon.

Although not illustrated, in one example in which quartz was bonded to the focus ring 120 by an adhesive, the film thickness of the heat insulating layer 130 was 1 mm plus the thickness of the adhesive and the porosity was 0%.

In one example in which special porous quartz was bonded to the focus ring 120 by an adhesive, the film thickness of the heat insulating layer 130 was 2 mm plus the thickness of the adhesive and the porosity was 35% or less.

In one example in which silicon was bonded to the focus ring 120 by an adhesive, the film thickness of the heat insulating layer 130 was 1 mm plus the thickness of the adhesive and the porosity was 0%.

From the foregoing results, the heat insulating layer 130 may be integrated with the focus ring 120 by plasma spraying, coating, dipping, and bonding. By this, the heat transfer within the focus ring 120 may be improved.

The heat insulating layer 130 may include at least one of zirconia, quartz, silicon carbide, and silicon nitride. However, the heat insulating layer 130 is formed using a material having a heat conductivity lower than that of the focus ring 120. For example, when the focus ring 120 is formed of silicon, the heat insulating layer 130 is formed using a material having a heat conductivity lower than that of the silicon. For example, when the focus ring 120 is formed of quartz, the heat insulating layer 130 is formed using a material having a heat conductivity lower than that of the quartz.

In particular, when the heat insulating layer 130 of zirconia was formed integrally with the focus ring 120 through plasma spraying among the processing methods described above, the temperature difference within the focus ring 120 becomes largest (see FIG. 4), a remarkable effect was obtained by providing the heat insulating layer 130.

In addition, the heat insulating layer 130 may be formed of a porous material having a porosity of 7% to 20%. In this way, the temperature difference within the focus ring 120 may also increase.

As described above, according to the plasma processing apparatus 1 of the present exemplary embodiment, among the surfaces of the focus ring 120, the heat insulating layer 130 is formed on the surface at the side of the polymer sheet 122 so that the temperature change occurring within the focus ring 120 may increase. As a result, as illustrated in FIG. 3, the temperature on the bottom surface of the focus ring 120 (the bottom surface of the heat insulating layer 130) may be maintained at about 160° C. even if the top surface of the focus ring 120 becomes a high temperature of 200° C. or more by the heat input from the plasma at the time of a high temperature process.

Therefore, even if the temperature of the top surface of the focus ring 120 rises by, for example, 50° C. or more, the temperature in the polymer sheet 122 does not rise, and as a result, the deterioration of the polymer sheet 122 may be suppressed so that reduction of the shelf life of the polymer sheet 122 may be avoided.

In the foregoing, the plasma processing apparatus and the focus ring have been described with reference to exemplary embodiments. However, the plasma processing apparatus and the focus ring according to the present disclosure are not limited to those exemplary embodiments and various variations and modifications may be made within the scope of the present disclosure. The features described in two or more of the exemplary embodiments described above may be combined with each other in a range that is not contradictory.

For example, a plasma processing apparatus, to which the focus ring according to the present disclosure is applicable, is not limited to the capacitively coupled plasma (CCP) processing apparatus described in the foregoing exemplary embodiments. The plasma processing apparatus, to which the focus ring according to the present disclosure is applicable, may be, for example, an inductively coupled plasma (ICP) processing apparatus, a chemical vapor deposition (CVD) apparatus using a radial line slot antenna, a helicon wave plasma (HWP) apparatus, or an electron cyclotron resonance (ECR) plasma apparatus.

Further, the substrate processed by the plasma processing apparatus according to the present disclosure is not limited to a wafer and may be, for example, a large substrate for use in a flat panel display, or a substrate for use in an EL device or a solar cell.

From the foregoing, it will be appreciated that various exemplary embodiments of the present disclosure have been described herein for purposes of illustration, and that various modifications may be made without departing from the scope and spirit of the present disclosure. Accordingly, the various exemplary embodiments disclosed herein are not intended to be limiting, with the true scope and spirit being indicated by the following claims.

What is claimed is:

1. A plasma processing apparatus comprising:
a focus ring installed outside a substrate mounted on a mounting table including a temperature control mechanism, and configured to be in contact with the mounting table via a heat transfer sheet,
wherein a heat insulating layer having a heat conductivity lower than that of the focus ring is provided on a surface of the focus ring at a side of the heat transfer sheet among surfaces of the focus ring.

2. The plasma processing apparatus of claim 1, wherein the focus ring is formed integrally with the heat insulating layer.

3. The plasma processing apparatus of claim 1, wherein the heat insulating layer includes a porous material having a predetermined porosity.

4. The plasma processing apparatus of claim 1, wherein the heat insulating layer includes at least one of zirconia, quartz, silicon carbide, and silicon nitride.

5. A focus ring installed outside a substrate mounted on a mounting table including a temperature control mechanism within a chamber where a plasma processing is performed, and configured to be in contact with the mounting table via a heat transfer sheet,
wherein a heat insulating layer having a heat conductivity lower than that of the focus ring is provided on a surface of the focus ring at a side of the heat transfer sheet among surfaces of the focus ring.
